(19) United States
(12) Patent Application Publication
(10) Pub. No.: US 2025/0204264 A1
(43) Pub. Date: Jun. 19, 2025

(54) SKYRMION TRANSISTOR AND METHOD OF CONTROLLING SKYRMION TRANSISTOR

(71) Applicant: INSTITUTE OF MICROELECTRONICS, CHINESE ACADEMY OF SCIENCES, Beijing (CN)

(72) Inventors: Guozhong XING, Beijing (CN); Hao ZHANG, Beijing (CN); Xuefeng ZHAO, Beijing (CN); Long LIU, Beijing (CN); Di WANG, Beijing (CN); Huai LIN, Beijing (CN); Ziwei WANG, Beijing (CN)

(21) Appl. No.: 18/847,854

(22) PCT Filed: Apr. 20, 2022
(86) PCT No.: PCT/CN2022/087852

§ 371 Date: Sep. 17, 2024

(30) Foreign Application Priority Data
Mar. 24, 2022 (CN) 202210296254.7

(51) Int. Cl. H10N 50/10; H10N 50/85

(52) U.S. Cl. CPC H10N 50/10; H10N 50/85

(57) ABSTRACT

The present disclosure provides a skyrmion transistor and a method of controlling a skyrmion transistor. The transistor includes: a ferromagnetic nanotube; a writing magnetic tunnel junction and a reading magnetic tunnel junction surrounding both ends of the ferromagnetic nanotube respectively; and a ferroelectric ring surrounding an outer side of the ferromagnetic nanotube and located between the writing magnetic tunnel junction and the reading magnetic tunnel junction, where the ferromagnetic nanotube and the ferroelectric ring form a ferromagnetic/ferroelectric heterojunction.

### CROSS REFERENCE TO RELATED APPLICATION(S)

This application is a Section 371 National Stage Application of International Application No. PCT/CN2022/087852, filed on Apr. 20, 2022, entitled “SKYRMION TRANSISTOR AND METHOD OF CONTROLLING SKYRMION TRANSISTOR”, which claims priority to Chinese Patent Application No. 202210296254.7 filed on Mar. 24, 2022, the content of which are incorporated herein by reference in their entireties.

### TECHNICAL FIELD

The present disclosure relates to a field of electronic technology, in particular to a skyrmion transistor and a method of controlling a skyrmion transistor.

### BACKGROUND

Skyrmion is a topologically protected non-collinear spin magnetic domain texture with quasi-particle characteristics, which has attracted more and more attention in a field of spintronics. With its characteristics such as an excellent stability, an extremely compact size, a 5-6 orders of magnitude lower driving current than a magnetic domain wall, etc., the skyrmion may be used as an information carrier in a next generation of information processing and data storage devices.

As a miniature variable current switch, a core of a traditional semiconductor transistor is to control an output current based on an input voltage and have an extremely fast switching speed. In contrast, in a skyrmion transistor, it is the skyrmion that is driven, not electrons. Therefore, a controlled dynamic process of the skyrmion is a key to achieve the skyrmion transistor. In order to meet a fast signal transmission, how to achieve a high-speed movement of the skyrmion is an urgent problem to be solved.

### SUMMARY

The present disclosure provides a skyrmion transistor and a method of controlling a skyrmion transistor.

In a first aspect, the present disclosure provides a skyrmion transistor, including: a ferromagnetic nanotube; a writing magnetic tunnel junction surrounding one end of the ferromagnetic nanotube; a reading magnetic tunnel junction surrounding the other end of the ferromagnetic nanotube; and a ferroelectric ring surrounding an outer side of the ferromagnetic nanotube and located between the writing magnetic tunnel junction and the reading magnetic tunnel junction, where the ferromagnetic nanotube and the ferroelectric ring form a ferromagnetic/ferroelectric heterojunction; after a first current is injected into the writing magnetic tunnel junction in a vertical direction, the ferromagnetic nanotube forms a skyrmion under an induction of the first current; after the first current is turned off and a second current in an axial direction is introduced into the ferromagnetic nanotube, the skyrmion moves in the axial direction under a driving of the second current; and a control voltage is applied to the ferroelectric ring, so as to control a movement state of the skyrmion by adjusting the control voltage.

In some embodiments, the skyrmion is a Bloch-type skyrmion or a Neel-type skyrmion.

In some embodiments, in a case that the skyrmion is the Bloch-type skyrmion, a material of the ferromagnetic nanotube includes one or more of: FeGe, MnGe, MnSi, MnNiGa, MnFeGe, FeCoSi and Cu₂OSeO₃.

In some embodiments, in a case that the skyrmion is the Neel-type skyrmion, a material of the ferromagnetic nanotube includes one or more of: Co, CoFeB, CoFe and FeNi.

In some embodiments, in a case that the skyrmion is the Neel-type skyrmion, the ferromagnetic nanotube has a hollow structure, the skyrmion transistor further includes a metal tube configured to provide an interface Dzyaloshinskii-Moriya Interaction DMI, and the metal tube is provided in the hollow structure of the ferromagnetic nanotube.

In some embodiments, a material of the metal tube includes one or more of: W, Ta, Pt, Pd, Ph, Ir, Pb and Au.

In some embodiments, the skyrmion transistor further includes a buffer layer located between the ferromagnetic nanotube and the ferroelectric ring.

In some embodiments, a material of the ferroelectric ring is lead zirconate titanate or lead magnesium niobate-lead titanate.

In a second aspect, the present disclosure provides a method of controlling a skyrmion transistor, applied to the skyrmion transistor provided in the first aspect, and the method includes: injecting the first current in the vertical direction into the writing magnetic tunnel junction of the skyrmion transistor, so that the ferromagnetic nanotube forms the skyrmion under the induction of the first current; turning off the first current, and introducing the second current in the axial direction into the ferromagnetic nanotube of the skyrmion transistor, so that the skyrmion moves in the axial direction under the driving of the second current; and applying the control voltage to the ferroelectric ring of the skyrmion transistor to adjust the movement state of the skyrmion.

In some embodiments, the applying the control voltage to the ferroelectric ring of the skyrmion transistor to adjust the movement state of the skyrmion includes: adjusting the control voltage to form an energy barrier region with a corresponding strength in the ferromagnetic nanotube below the ferroelectric ring; where in a case that the skyrmion passes through the energy barrier region and reaches the reading magnetic tunnel junction of the skyrmion transistor under the driving of the second current, the skyrmion transistor is turned on; and in a case that the skyrmion is blocked by the energy barrier region under the driving of the second current, the skyrmion transistor is turned off.

### BRIEF DESCRIPTION OF THE DRAWINGS

In order to clearly describe the technical solutions in the embodiments of the present disclosure, accompanying drawings required for the description of the embodiments of the present disclosure will be briefly introduced below. Obviously, the accompanying drawings in the following descriptions are for some of the embodiments of the present disclosure. For those ordinary skilled in the art, other accompanying drawings may also be obtained according to these accompanying drawings without any creative work.

FIG. 1 shows a schematic diagram of a skyrmion transistor according to the embodiments of the present disclosure;

FIG. 2 shows a schematic cross-sectional view of a ferromagnetic/ferroelectric heterojunction of a skyrmion transistor when a skyrmion is a Neel-type skyrmion according to the embodiments of the present disclosure;

FIG. 3 shows a schematic cross-sectional view of a ferromagnetic/ferroelectric heterojunction of a skyrmion transistor when a skyrmion is a Bloch-type skyrmion according to the embodiments of the present disclosure;

FIG. 4 shows a schematic diagram of a position of a skyrmion in a skyrmion transistor when a first current is injected into the skyrmion transistor according to the embodiments of the present disclosure;

FIG. 5 shows a schematic diagram of a position of a skyrmion in a skyrmion transistor when a first current is turned off and a second current is injected into the skyrmion transistor according to the embodiments of the present disclosure;

FIG. 6 shows a schematic diagram of a position of a skyrmion which may not pass through an energy barrier when a first current is turned off, a second current is injected into a skyrmion transistor and a control voltage is applied, according to the embodiments of the present disclosure;

FIG. 7 shows a schematic diagram of a position of a skyrmion which passes through an energy barrier when a first current is turned off, a second current is injected into a skyrmion transistor and a control voltage is applied, according to the embodiments of the present disclosure;

FIG. 8 shows a schematic diagram of a velocity component of a skyrmion according to the embodiments of the present disclosure;

FIG. 9 shows a schematic diagram of a relationship between an anisotropic parameter of a gate region and an axial current density according to the embodiments of the present disclosure; and

FIG. 10 shows a flowchart of a method of controlling a skyrmion transistor according to the embodiments of the present disclosure.

### DETAILED DESCRIPTION OF EMBODIMENTS

The embodiments of the present disclosure will be described below with reference to the accompanying drawings. It should be understood, however, that these descriptions are merely exemplary and are not intended to limit the scope of the present disclosure. In addition, in the following descriptions, descriptions of well-known structures and technologies are omitted to avoid unnecessarily obscuring the concept of the present disclosure.

Various schematic structural diagrams according to the embodiments of the present disclosure are shown in the accompanying drawings. The drawings are not drawn to scale. Some details are enlarged and some details may be omitted for clarity of presentation. Shapes of the various regions and layers as well as a relative size and a positional relationship thereof shown in the drawings are only exemplary. In practice, there may be deviations due to manufacturing tolerances or technical limitations, and those skilled in the art may additionally design regions/layers with different shapes, sizes, and relative positions according to actual needs.

In the context of the present disclosure, when a layer/element is referred to as being located “on” a further layer/element, the layer/element may be directly on the further layer/element, or there may be an intermediate layer/element therebetween. In addition, if a layer/element is located “on” a further layer/element in one orientation, the layer/element may be located “under” the further layer/element when the orientation is reversed.

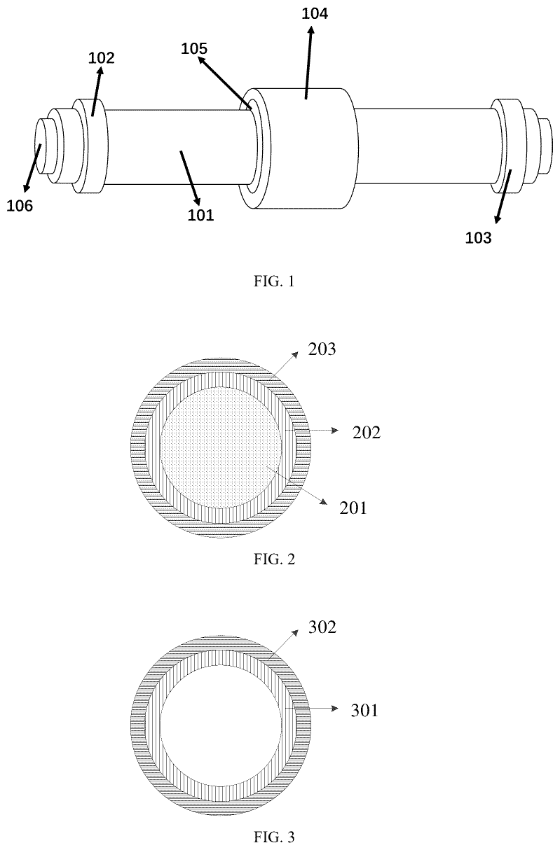

The embodiments of the present disclosure provide a skyrmion transistor. FIG. 1 is a schematic diagram of the skyrmion transistor provided by the embodiments of the present disclosure.

The skyrmion transistor includes: a ferromagnetic nanotube 101; a writing magnetic tunnel junction 102 surrounding one end of the ferromagnetic nanotube 101; a reading magnetic tunnel junction 103 surrounding the other end of the ferromagnetic nanotube 101; and a ferroelectric ring 104 surrounding an outer side of the ferromagnetic nanotube 101 and located between the writing magnetic tunnel junction 102 and the reading magnetic tunnel junction 103, where the ferromagnetic nanotube 101 and the ferroelectric ring 104 form a ferromagnetic/ferroelectric heterojunction.

In the embodiments of the present disclosure, the ferromagnetic nanotube 101 may generate a stable skyrmion and provide a channel for a directional high-speed movement of the skyrmion. The ferromagnetic nanotube 101 has a borderless tubular structure, which may be a hollow tubular structure or a solid tubular structure.

The writing magnetic tunnel junction 102 and the reading magnetic tunnel junction 103 surround two ends of the ferromagnetic nanotube respectively, as shown in FIG. 1. Each of the writing magnetic tunnel junction 102 and the reading magnetic tunnel junction 103 may have a sandwich structure of ferromagnetic layer-barrier layer-ferromagnetic layer. Taking the writing magnetic tunnel junction 102 as an example, it may be specifically formed by: forming a barrier layer on a surface of one end of the ferromagnetic nanotube 101, and then forming a ferromagnetic layer on the barrier layer. A material of the barrier layer may be metal oxide, such as MgO. The writing magnetic tunnel junction 102 may be provided on the ferromagnetic nanotube 101 in a circumferential surrounding manner, or it may be provided on the ferromagnetic nanotube 101 in a partial surrounding manner, such as a quarter circumference, an eighth circumference, etc. The reading magnetic tunnel junction 103 is usually provided on the ferromagnetic nanotube 101 in a circumferential surrounding manner. Certainly, the surrounding manner of the reading magnetic tunnel junction 103 may be modified according to actual needs, which will not be limited here.

The ferroelectric ring 104 is formed in the middle of the ferromagnetic nanotube 101. A material of the ferroelectric ring 104 may be lead zirconate titanate (PZT) or lead magnesium niobate-lead titanate (PMN-PT). The ferromagnetic nanotube 101 and the ferroelectric ring 104 form the ferromagnetic/ferroelectric heterojunction.

In some embodiments, considering that the ferroelectric ring 104 may deform and squeeze the ferromagnetic nanotube 101 under an action of an external electric field during an operation process of the transistor, if a stress is too large, the ferromagnetic nanotube 101 may be damaged. Therefore, a buffer layer 105 (as shown in FIG. 1) may be provided between the ferromagnetic nanotube 101 and the ferroelectric ring 104. A material of the buffer layer 105 may be a metal material, such as tantalum, ruthenium, etc. In the skyrmion transistor provided with the buffer layer 105, the ferromagnetic nanotube 101, the buffer layer 105 and the ferroelectric ring 104 form the ferromagnetic/ferroelectric heterojunction. It should be noted that whether the buffer layer is provided may be set according to actual needs, such as adding or canceling the buffer layer according to a material, a thickness, etc. of the ferromagnetic nanotube 101.

In the structure of the skyrmion transistor shown in FIG. 1, the writing magnetic tunnel junction 102, the ferromagnetic/ferroelectric heterojunction and the reading magnetic tunnel junction 103 are used as a source, a gate and a drain of the skyrmion transistor respectively.

It should be noted that the ferromagnetic nanotube 101 that provides an orbit for the skyrmion may include various structures, so as to generate different types of skyrmions. In the embodiments of the present disclosure, structures in which a Neel-type skyrmion and a Bloch-type skyrmion are generated at the source are respectively taken as examples for description.

### I. Generating a Neel-Type Skyrmion

FIG. 2 shows a schematic cross-sectional view of a ferromagnetic/ferroelectric heterojunction of a skyrmion transistor when a skyrmion is a Neel-type skyrmion. In the structure, the ferromagnetic nanotube 101 has a hollow structure, which is similar to a ring structure with holes. The skyrmion transistor further includes a metal tube 106 for providing an interface DMI, and the metal tube 106 is provided in the hollow structure of the ferromagnetic nanotube. An outer diameter of the metal tube 106 may be the same as an inner diameter of the hollow structure. The metal tube may be a hollow tube or a solid tube. A length of the metal tube 106 may be set according to actual needs.

As shown in FIG. 2, the structure includes a metal layer 201 provided by the metal tube 106, a first ferromagnetic layer 202 provided by the ferromagnetic nanotube 101, and a first ferroelectric layer 203 provided by the ferroelectric ring 104 from inside to outside. A material of the ferromagnetic nanotube 101 includes one or more of: FeGe, MnGe, MnSi, MnNiGa, MnFeGe, FeCoSi and Cu₂OSeO₃. A material of the metal tube 106 may include one or more of: W, Ta, Pt, Pd, Ph, Ir, Pb and Au. In addition, a buffer layer may be added between the ferroelectric ring 104 and the ferromagnetic nanotube 101 as needed.

This structure has an interface DMI (Dzyaloshinskii-Moriya interaction) between the metal layer 201 and the first ferromagnetic layer 202, which induces the generation of the Neel-type skyrmion.

### II. Generating a Bloch-Type Skyrmion

FIG. 3 shows a schematic cross-sectional view of a ferromagnetic/ferroelectric heterojunction of a skyrmion transistor when a skyrmion is a Bloch-type skyrmion. In the structure, a bulk DMI is provided by the ferromagnetic nanotube 101, and there is no need to provide the interface DMI by the metal layer 201 in FIG. 2. In some embodiments, a material of the ferromagnetic nanotube 101 includes one or more of: FeGe, MnGe, MnSi, MnNiGa, MnFeGe, FeCoSi and Cu₂OSeO₃.

As shown in FIG. 3, the structure includes a second ferromagnetic layer 301 provided by the ferromagnetic nanotube 101 and a second ferroelectric layer 302 provided by the ferroelectric ring 104 from inside to outside. In the structure, the ferromagnetic nanotube 101 may have a hollow structure, and an interior of the hollow structure is not filled. The ferromagnetic nanotube 101 may also have a solid structure, with no holes in its cross section.

In this structure, the second ferromagnetic layer 301 has a bulk DMI, which induces the generation of the Bloch-type skyrmion.

In the embodiments of the present disclosure, a working process of the skyrmion transistor is as follows: after a first current is injected into the writing magnetic tunnel junction 102 in a vertical direction, the ferromagnetic nanotube 101 forms a skyrmion under an induction of the first current; after the first current is turned off and a second current in an axial direction is introduced into the ferromagnetic nanotube 101, the skyrmion moves in the axial direction under a driving of the second current; and a control voltage is applied to the ferroelectric ring 104, so as to control a movement state of the skyrmion by adjusting the control voltage.

The vertical direction is a direction perpendicular to an axis of the ferromagnetic nanotube 101, and the axial direction is an axis direction of the ferromagnetic nanotube 101. Specific values of the first current and the second current may be set according to actual needs, which will not be limited here.

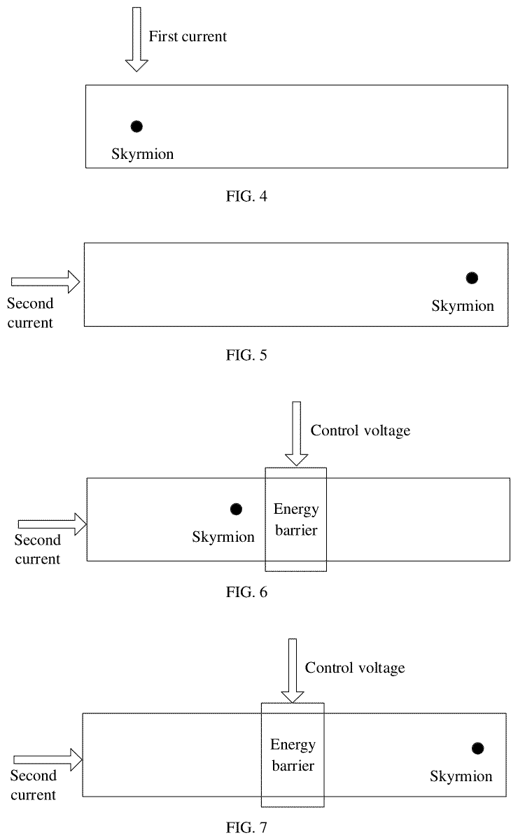

As shown in FIG. 4, the first current is injected into the writing magnetic tunnel junction 102 in the vertical direction and then polarized into a spin polarized current, which induces the ferromagnetic nanotube 101 below the writing magnetic tunnel junction 102 to form a stable skyrmion. The ferromagnetic nanotube 101 in the embodiments of the present disclosure may provide a bulk DMI or an interface DMI, and may achieve a stable generation of the skyrmion at the source. Since the skyrmion has a particle-like domain wall structure protected by topology, its stability far exceeds that of a traditional magnetic domain wall. Even if the skyrmion is pinned by defects or accidentally annihilated, it may be regenerated through the above steps. Theoretically, there is no upper limit on the number of times of generation of the skyrmion, so the skyrmion transistor has strong anti-damage characteristics.

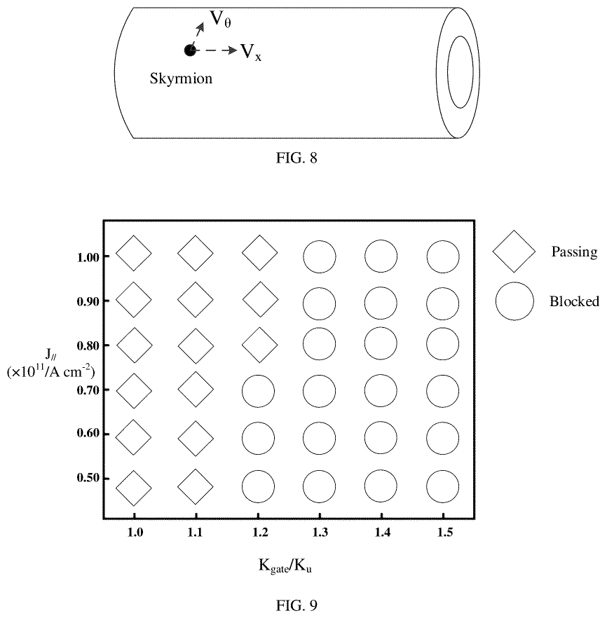

As shown in FIG. 5, after the generation of the skyrmion, the first current in the vertical direction is turned off, the second current in the axial direction is introduced and polarized into a spin polarized current, and the skyrmion moves to the gate under a driving of the spin polarized current. As shown in FIG. 8, the skyrmion has an axial velocity VX. At the same time, influenced by the Hall effect of the skyrmion, a movement direction of the skyrmion may gradually shift from a direction driven by the current. According to the Thiele equation, the skyrmion further has a velocity component Vₑ perpendicular to the movement direction. Therefore, the skyrmion may move in a spiral trajectory along the ferromagnetic nanotube 101.

In the embodiments of the present disclosure, since the ferromagnetic nanotube 101 uses a borderless tubular design, the skyrmion may not be accumulated or even annihilated at a boundary during the movement. Thanks to a lifting of boundary constraint, the skyrmion may move at a high speed under an action of a large second current. At this time, the skyrmion transistor is in an on-state.

As shown in FIG. 6, when the first current is turned off, the second current is introduced and the control voltage is applied to the gate, the ferroelectric ring 104 has a radial strain under an action of an electric field, and the strain may be further mediated to the ferromagnetic nanotube 101 through the ferromagnetic/ferroelectric heterojunction. Anisotropy of the ferromagnetic nanotube 101 increases under an action of the reverse magnetostrictive effect (magnetoelastic effect), resulting in a voltage-controlled energy barrier in a gate region. The energy barrier E_{gate} may be expressed by the following equation.

$${E}_{gate} = - {{K}_{gate} ( m \cdot \hat{z} )}^{2}$$

In the equation, K_{gate} is an anisotropic parameter of the gate region, that is, an anisotropic parameter of the ferroelectric ring; m is a magnetization intensity; and \hat{z} is a parameter related to a unit vertical direction.

When an axial current density corresponding to the second current is low, the skyrmion is blocked out of an energy barrier region. At this time, the skyrmion transistor is in an off-state.

As shown in FIG. 7, as the axial current density increases continuously, the velocity of the skyrmion increases to a certain extent, and the skyrmion may break through the energy barrier region to reach the drain. At this time, the state of the skyrmion transistor is re-switched to the on-state.

In the embodiments of the present disclosure, the reading magnetic tunnel junction 103 may determine whether the skyrmion has reached the drain according to a tunneling magnetoresistance effect (TMR). In a specific implementation process, a resistance of the tunnel junction may be read. If the resistance does not change, it is indicated that the skyrmion has not entered the drain. If the resistance changes, it is indicated that the skyrmion has entered the drain.

Therefore, the function of the skyrmion transistor may be achieved by adjusting the anisotropic parameter of the gate region and the axial current density corresponding to the second current. It should be noted that, in order to increase a storage density, a diameter of the ferromagnetic nanotube 101 may be set to the order of tens of nanometers in the embodiments of the present disclosure.

FIG. 9 shows a schematic diagram of a relationship between an anisotropic parameter K_{gate} of the gate region and an axial current density J_{//}. K_{gate} may be regulated according to a magnetoelectric coupling effect between the ferroelectric ring 104 and the ferromagnetic nanotube 101. As shown in FIG. 9, Kᵤ is an anisotropic parameter of the ferroelectric nanotube. As a ratio of K_{gate}/Kᵤ gradually increases from 1 to 1.5 and the axial current density J_{//} increases continuously, the state of the skyrmion changes from “successfully passing” to “completely blocked”.

In an embodiment, the skyrmion transistor provided by the embodiments of the present disclosure is simulated. The skyrmion may pass through the energy barrier in a state of K_{gate}/Kᵤ=1.2 and J_{//}=8×10¹⁰ A/cm². The skyrmion may not pass through the energy barrier in a state of K_{gate}/Kᵤ=1.2 and J_{//}=7×10¹⁰ A/cm².

In view of above, the skyrmion transistor provided by the embodiments of the present disclosure at least has the following beneficial effects.

(1) By inducing the generation of the skyrmion through the spin polarized current and regulating the energy barrier in the gate region through the magnetoelectric coupling effect, a switching of the skyrmion between two states of passing through the energy barrier and being blocked by the energy barrier may be achieved through a relationship between different axial current densities and strength of the energy barrier region, thereby achieving the function of the transistor. The skyrmion transistor provided by the present disclosure has a simple structure, a small size, a lower power consumption, a better stability and a high repeatability.

(2) The skyrmion transistor provided by the present disclosure uses a ferroelectric material, and anisotropy of the ferromagnetic/ferroelectric heterojunction region is adjusted by strain. Compared with direct use of VCMA (Voltage Control Magnetic Anisotropy) to regulate the anisotropy, the present disclosure is more efficient in regulating the anisotropy, and does not require an additional dielectric layer provided between the ferroelectric ring and the ferromagnetic nanotube. Therefore, the skyrmion transistor provided by the present disclosure has a higher damage resistance.

(3) The skyrmion provided by the present disclosure uses a borderless tubular structure with no need to consider the influence of the Hall effect. The skyrmion may move at a high speed under a driving of a large current. Therefore, an information transmission speed of the skyrmion is higher than that of a transistor with a planar thin film structure.

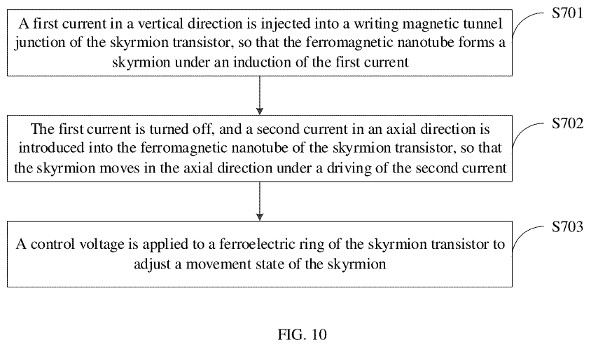

Based on the same concept, the embodiments of the present disclosure further provide a method of controlling a skyrmion transistor, which is applied to the skyrmion transistor provided above. As shown in FIG. 10, the method includes the following steps S701 to S703.

In step S701, a first current in a vertical direction is injected into a writing magnetic tunnel junction of the skyrmion transistor, so that the ferromagnetic nanotube forms a skyrmion under an induction of the first current.

In step S702, the first current is turned off, and a second current in an axial direction is introduced into the ferromagnetic nanotube of the skyrmion transistor, so that the skyrmion moves in the axial direction under a driving of the second current.

In step S703, a control voltage is applied to a ferroelectric ring of the skyrmion transistor to adjust a movement state of the skyrmion.

In some embodiments, the applying the control voltage to the ferroelectric ring of the skyrmion transistor to adjust the movement state of the skyrmion includes the following steps.

The control voltage is adjusted to form an energy barrier region with a corresponding strength in the ferromagnetic nanotube below the ferroelectric ring.

In a case that the skyrmion passes through the energy barrier region and reaches the reading magnetic tunnel junction of the skyrmion transistor under the driving of the second current, the skyrmion transistor is turned on; and in a case that the skyrmion is blocked by the energy barrier region under the driving of the second current, the skyrmion transistor is turned off.

The above-mentioned method of controlling the skyrmion transistor has been described in detail in the embodiments of the skyrmion transistor provided in the present disclosure, which will not be described in detail here.

The skyrmion transistor provided by the present disclosure includes a ferromagnetic nanotube, a writing magnetic tunnel junction, a reading magnetic tunnel junction and a ferroelectric ring. The writing magnetic tunnel junction and the reading magnetic tunnel junction surround two ends of the ferromagnetic nanotube respectively; the ferroelectric ring surrounds an outer side of the ferromagnetic nanotube and is located between the writing magnetic tunnel junction and the reading magnetic tunnel junction, and the ferromagnetic nanotube and the ferroelectric ring form a ferromagnetic/ferroelectric heterojunction. When a first current in a vertical direction is injected into the writing magnetic tunnel junction, the ferromagnetic nanotube forms a skyrmion under an induction of the first current; after the first current is turned off and a second current in an axial direction is introduced into the ferromagnetic nanotube, the skyrmion moves in the axial direction under a driving of the second current; a control voltage is applied to the ferroelectric ring, so that a movement state of the skyrmion is controlled by adjusting the control voltage. In the above-mentioned solution, since the ferromagnetic nanotube used to generate the skyrmion and used as a movement carrier of the skyrmion has a borderless tubular structure, the skyrmion may move in a spiral manner along a surface of the ferromagnetic nanotube without being affected by the Hall effect of the skyrmion and without being annihilated at a boundary, thereby greatly improving a movement speed of the skyrmion and achieving a great improvement of a signal transmission of the transistor.

In the above-mentioned descriptions, the technical details such as patterning and forming of each structure of the device have not been described in detail. However, those skilled in the art should understand that various technical means may be used to form layers, regions, etc. of desired shapes. For example, dimensions of devices and layers may be miniaturized according to the process, shapes thereof may be simply replaced, and positions of the writing magnetic tunnel junction, the reading magnetic tunnel junction and the ferromagnetic/ferroelectric heterojunction may be changed. In addition, in order to form the same structure, those skilled in the art may further design a method that is not exactly the same as the method described above. In addition, although the various embodiments have been described above separately, this does not mean that the measures in the various embodiments may not be advantageously used in combination.

Although the preferred embodiments of the present disclosure have been described, those skilled in the art may make additional changes and modifications to these embodiments once they know the basic inventive concept. Therefore, the appended claims are intended to be interpreted as all changes and modifications that include the preferred embodiments and fall within the scope of the present disclosure.

Obviously, those skilled in the art may make various modifications and variations to the present disclosure without departing from the spirit and principles of the present disclosure. Therefore, if these modifications and variations of the present disclosure fall within the scope of the claims of the present disclosure and their equivalents, the present disclosure is also intended to include these modifications and variations.

1. A skyrmion transistor, comprising:
a ferromagnetic nanotube;
a writing magnetic tunnel junction surrounding one end of the ferromagnetic nanotube;
a reading magnetic tunnel junction surrounding the other end of the ferromagnetic nanotube; and
a ferroelectric ring surrounding an outer side of the ferromagnetic nanotube and located between the writing magnetic tunnel junction and the reading magnetic tunnel junction, wherein the ferromagnetic nanotube and the ferroelectric ring form a ferromagnetic/ferroelectric heterojunction;
wherein after a first current is injected into the writing magnetic tunnel junction in a vertical direction, the ferromagnetic nanotube forms a skyrmion under an induction of the first current; after the first current is turned off and a second current in an axial direction is introduced into the ferromagnetic nanotube, the skyrmion moves in the axial direction under a driving of the second current; and a control voltage is applied to the ferroelectric ring, so as to control a movement state of the skyrmion by adjusting the control voltage.

2. The skyrmion transistor according to claim 1, wherein the skyrmion is a Bloch-type skyrmion or a Neel-type skyrmion.

3. The skyrmion transistor according to claim 2, wherein in a case that the skyrmion is the Bloch-type skyrmion, a material of the ferromagnetic nanotube comprises one or more of: FeGe, MnGe, MnSi, MnNiGa, MnFeGe, FeCoSi and Cu₂OSeO₃.

4. The skyrmion transistor according to claim 2, wherein in a case that the skyrmion is the Neel-type skyrmion, a material of the ferromagnetic nanotube comprises one or more of: Co, CoFeB, CoFe and FeNi.

5. The skyrmion transistor according to claim 2, wherein in a case that the skyrmion is the Neel-type skyrmion, the ferromagnetic nanotube has a hollow structure, the skyrmion transistor further comprises a metal tube configured to provide an interface Dzyaloshinskii-Moriya Interaction DMI, and the metal tube is provided in the hollow structure of the ferromagnetic nanotube.

6. The skyrmion transistor according to claim 5, wherein a material of the metal tube comprises one or more of: W, Ta, Pt, Pd, Ph, Ir, Pb and Au.

7. The skyrmion transistor according to claim 1, further comprising:
a buffer layer located between the ferromagnetic nanotube and the ferroelectric ring.

8. The skyrmion transistor according to claim 1, wherein a material of the ferroelectric ring is lead zirconate titanate or lead magnesium niobate-lead titanate.

9. A method of controlling a skyrmion transistor, applied to the skyrmion transistor of claim 1, wherein the method comprises:
injecting the first current in the vertical direction into the writing magnetic tunnel junction of the skyrmion transistor, so that the ferromagnetic nanotube forms the skyrmion under the induction of the first current;
turning off the first current, and introducing the second current in the axial direction into the ferromagnetic nanotube of the skyrmion transistor, so that the skyrmion moves in the axial direction under the driving of the second current; and
applying the control voltage to the ferroelectric ring of the skyrmion transistor to adjust the movement state of the skyrmion.

10. The method according to claim 9, wherein the applying the control voltage to the ferroelectric ring of the skyrmion transistor to adjust the movement state of the skyrmion comprises:
adjusting the control voltage to form an energy barrier region with a corresponding strength in the ferromagnetic nanotube below the ferroelectric ring;
wherein in a case that the skyrmion passes through the energy barrier region and reaches the reading magnetic tunnel junction of the skyrmion transistor under the driving of the second current, the skyrmion transistor is turned on; and in a case that the skyrmion is blocked by the energy barrier region under the driving of the second current, the skyrmion transistor is turned off.
